(19) United States
(12) Patent Application Publication
(10) Pub. No.: US 2024/0394552 A1
(43) Pub. Date: Nov. 28, 2024

(54) Routability-Aware Large-Scale Transistor-Level Placement Using Reinforcement Learning

(71) Applicant: X DEVELOPMENT LLC, Mountain View, CA (US)

(72) Inventors: Xiaoqing Xu, Mountain View, CA (US); Wenjie Jiang, San Carlos, CA (US); Chia-tung Ho, La Jolla, CA (US)

(21) Appl. No.: 18/202,029

(22) Filed: May 25, 2023

(51) Int. Cl. G06N 3/092

(52) U.S. Cl. CPC G06N 3/092

(57) ABSTRACT

The technology provides techniques for optimizing transistor-level placement using a hybrid approach involving reinforcement learning (“RL”) in conjunction with an optimization technique. This can include implementing an iterative RL training process for an integrated circuit to train a RL agent, including the RL agent learning an ordering of transistors for the integrated circuit by placement of one transistor on an encoded grid per iteration. The RL agent iterates until all transistors for the integrated circuit are placed on the encoded grid. Upon placing all the transistors on the encoded grid, one or more processors implement a solver module using the ordering of the transistors as an input. The solver module is configured to perform an optimization to minimize spacing between the transistors. The trained reinforcement learning agent can then be save in memory.

### BACKGROUND

In many instances, integrated circuit (IC) physical design targets standard cell-based digital designs, where each object to be placed is either a standard cell or a hard macro and each net denotes the logic connection among various input/output pins associated with the objects or input/output of the design. This approach often involves labor-intensive manual design in an attempt to optimize the power-performance-area-cost (PPAC) of standard cells. However, due to the complexity of design rules and limited routing resources in the standard cells at sub-7 nm, it can be very challenging to generate optimal standard cell layout in terms of PPAC. The challenge can increase as the number of objects to be placed exceeds scores, hundreds or thousands of transistors, especially when standard cell architectures may only support very limited numbers of transistors.

### BRIEF SUMMARY

Aspects of the technology relate to the design and fabrication of IC devices, and more particularly to techniques for optimizing transistor-level placement using a hybrid approach involving reinforcement learning (“RL”) in conjunction with an optimization technique. RL is a type of machine learning training that is based on an approach that rewards desired behaviors and/or does not reward undesired behaviors. The RL action space can be processed by a set of processing elements configured to perform distributed RL. The RL process involves the system learning and generating the order of transistors that are placed on a coded grid (canvas). This process may be driven by optimization proxies, such as routability, timing and/or power proxies. Once the transistors are ordered, an optimization process is performed. The optimization process may employ a Boolean Satisfiability (or SAT) solver, a Satisfiability Modulo a Theory (SMT) solver, a Mixed-Integer Linear Programming (MILP) approach, or other type of solver.

According to one aspect of the technology, a computer-implemented processing system is provided. The system comprises a memory configured to store a reinforcement learning agent and a solver module, and one or more processors operatively coupled to the memory. The one or more processors are configured to: implement an iterative reinforcement learning training process for an integrated circuit to train the reinforcement learning agent. The reinforcement learning agent learns an ordering of transistors for the integrated circuit by placement of one transistor on an encoded grid per iteration. The reinforcement learning agent is configured to iterate until all transistors for the integrated circuit are placed on the encoded grid. Then upon placement of all the transistors on the encoded grid, the processor(s) implements the solver module using the ordering of the transistors as an input. The solver module is configured to perform an optimization to minimize spacing between the transistors. The resultant trained reinforcement learning agent can be stored in the memory.

The one or more processors may be further configured to generate an integrated circuit design according to the optimization. The reinforcement learning agent may learn the ordering of transistors for the integrated circuit by placing either the one transistor on the encoded grid per iteration or by placing a pair of complementary transistors on the encoded grid per iteration. The reinforcement learning agent may employs a policy proximal optimization according to an RL action space. Here, the policy proximal optimization may implement a probability distribution for every transistor for where that could be placed on the encoded grid.

The one or more processors may be further configured to implement a router module after one or more intermediate iterations of the iterative reinforcement learning training process. The solver module may implement at least one of a Boolean Satisfiability solver, a Satisfiability Modulo a Theory (SMT) solver, or a Mixed-Integer Linear Programming (MILP) solver. The reinforcement learning agent may learn the ordering of transistors according to actions, states and rewards for each iteration, in which each state includes connectivity and coordinates of previously placed transistors on the encoded grid. In this case, the reward at an end of each iteration may be calculated as a linear combination of cell area, wirelength, and any routability or timing penalty. Cell area may be defined by a minimum bounding box that includes all currently placed transistors at a given iteration. The minimum bounding box may represent a half-perimeter wire length. Alternatively or additionally to the above, the reward at a conclusion of a final iteration may be back-propagated through the reinforcement learning agent. Moreover, in any configuration routability at each iteration can approximated using at least one of congestion, pin density, area or wire length.

According to another aspect, a computer-implemented method is provided that comprises: implementing, by one or more processors of a processing system, an iterative reinforcement learning training process for an integrated circuit to train a reinforcement learning agent, including the reinforcement learning agent learning an ordering of transistors for the integrated circuit by placement of one transistor on an encoded grid per iteration, in which the reinforcement learning agent iterates until all transistors for the integrated circuit are placed on the encoded grid; upon placing all the transistors on the encoded grid, the one or more processors implementing a solver module using the ordering of the transistors as an input, the solver module being configured to perform an optimization to minimize spacing between the transistors; and saving the trained reinforcement learning agent in memory.

The method may further comprise generating an integrated circuit design according to the optimization. Learning the ordering of transistors for the integrated circuit by the reinforcement learning agent may include placing either the one transistor on the encoded grid per iteration or by placing a pair of complementary transistors on the encoded grid per iteration. The reinforcement learning agent may employ a policy proximal optimization according to an RL action space. Alternatively or additionally, the method may further comprise the one or more processors implementing a router module after one or more intermediate iterations of the iterative reinforcement learning training process. The solver module may implement at least one of a Boolean Satisfiability solver, a Satisfiability Modulo a Theory (SMT) solver, or a Mixed-Integer Linear Programming (MILP) solver. The reinforcement learning agent may learn the ordering of transistors according to actions, states and rewards for each iteration, in which each state includes connectivity and coordinates of previously placed transistors on the encoded grid.

### BRIEF DESCRIPTION OF THE DRAWINGS

FIGS. 1A-B illustrate exemplary transistors in accordance with aspects of the technology.

FIG. 2 illustrates a figure for general transistor placement example.

FIGS. 3A-3B illustrate examples of transistor placement using an encoded grid in accordance with aspects of the technology.

FIG. 4 illustrates an iterative agent-based RL approach in accordance with aspects of the technology.

FIG. 5 illustrates an exemplary minimum bounding box for use with aspects of the technology.

FIGS. 6A-B illustrate an exemplary system in accordance with aspects of the technology.

FIG. 7 illustrates a flow diagram for a method according to aspects of the technology.

### DETAILED DESCRIPTION

For large-scale transistor-level placement, it is desirable to minimize the total area of the integrated circuit device. This can be viewed as minimizing wirelength and area, given a netlist with constant interconnects and nets.

In a typical process, chip components may generally be designed from standard cells that are formed using fixed groups of transistors. This standard cell design approach can become very challenging as the device size shrinks (e.g., below 5-7 nm for transistor-type devices). Manual designs can take on the order of 3-6 months or more to deliver a suitable library set. This is obviously very time consuming, which can delay the release of new products or updates to existing products. While certain approaches have been automated in some instances, this may only be suitable for small-scale devices with up to a few dozen transistors. Scalability, or the need to create integrated circuit layouts for devices with hundreds or thousands of transistors, appears to be beyond the scope of known approaches.

In view of this, according to aspects of the technology, transistor-level placement optimization may be performed using a hybrid approach involving both reinforcement learning and optimization. This can result in not only much faster generation of a library set than manual design, but also more efficient placement of individual transistors. Interconnections may also use less metal, which is particularly desirable as device size shrinks. Other benefits for the hybrid approach discussed herein can include smaller IC device area, better (e.g., faster) performance, and reduced power consumption.

As noted above, RL is machine learning-based training approach that rewards desired behaviors and/or does not reward undesired behaviors. According to aspects of the technology discussed herein, a Reinforcement Learning (“RL”) agent learns and generates the order of transistors using an encoded grid, and optimization is applied to co-optimize the power-performance-area (PPA) of large-scale transistor-level placement. By way of example, diffusion sharing and routability may be determined by simulated horizontal/vertical congestions or an SMT (or other) solver, while the RL agent determines the sequence of transistor placement over many iterations of training. This approach may be applied to single-row or multi-row architectures using the encoded grid.

The RL approach may employ a policy proximal optimization (PPO) according to an RL action space. The action space encompasses the set of all valid actions (here, choices) available to the RL agent as it performs its optimization. The policy is a function mapping the RL agent's state to its next action. More particularly, the policy involves a probability distribution for every transistor for where it could be placed on the canvas. The system places one transistor at a time, evaluating the current context to identify what the probability is to place the next transistor. A goal is to improve the probability over time.

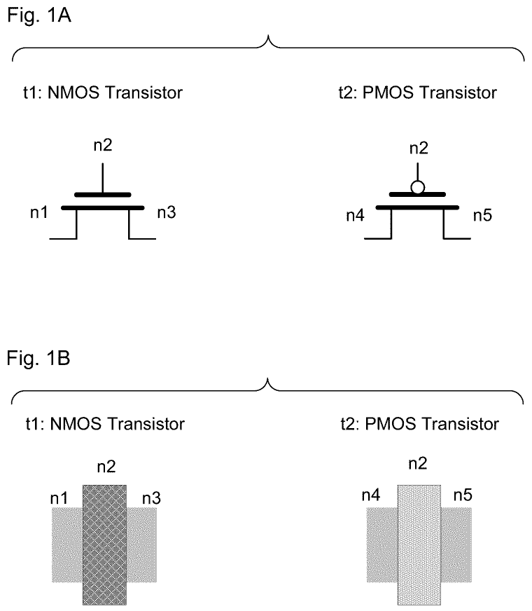

Exemplary individual transistors, such as NMOS-type transistor t1 and PMOS-type transistor t2 are illustrated in FIGS. 1A-B. Each of these transistors is represented as a 3-terminal device (as shown in FIG. 1A) having a source, a gate, and a drain. Each terminal for a given transistor is connected to a net (e.g., n1, n2 and n3 for t1, and n2, n4 and n5 for t2). Each net denotes the logic connection among various input/output pins associated with the transistors of interest. FIG. 1B illustrates stylized doping views for the terminals.

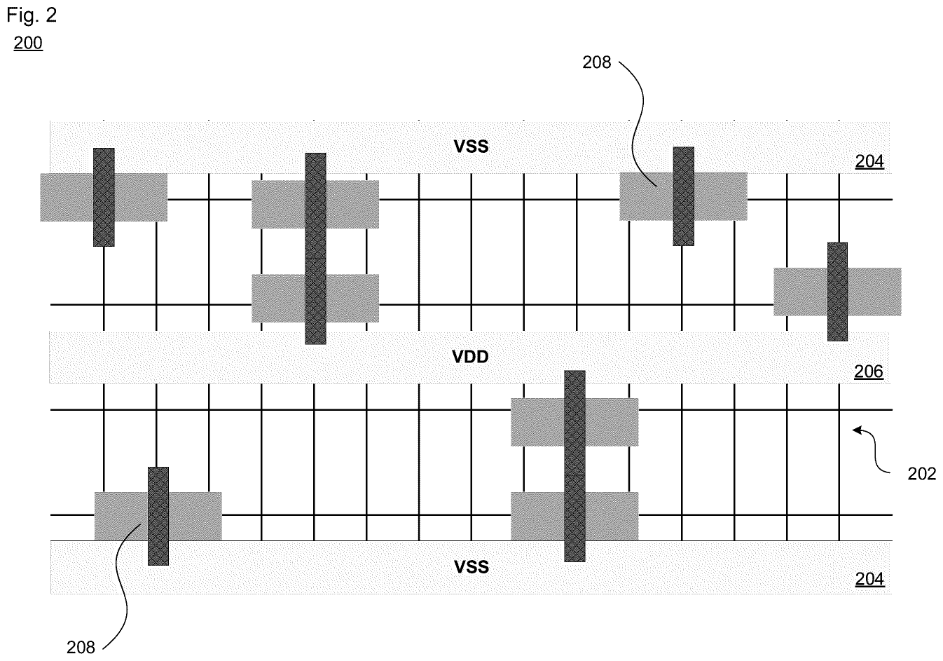

As shown in the general example 200 of FIG. 2, given a transistor netlist with net connection information, transistors can be placed in a placement grid to satisfy diffusion breaks and sharing rules. Grid 202 is shown with voltage source supply (VSS) 204 and voltage drain supply (VDD) 206 power lines, with transistors 208 disposed n the grid. SAT placement or another solver approach can be used. However, without knowing the order for transistor placement, the solver may run very slowly, creating a significant bottleneck in the design and fabrication of IC devices.

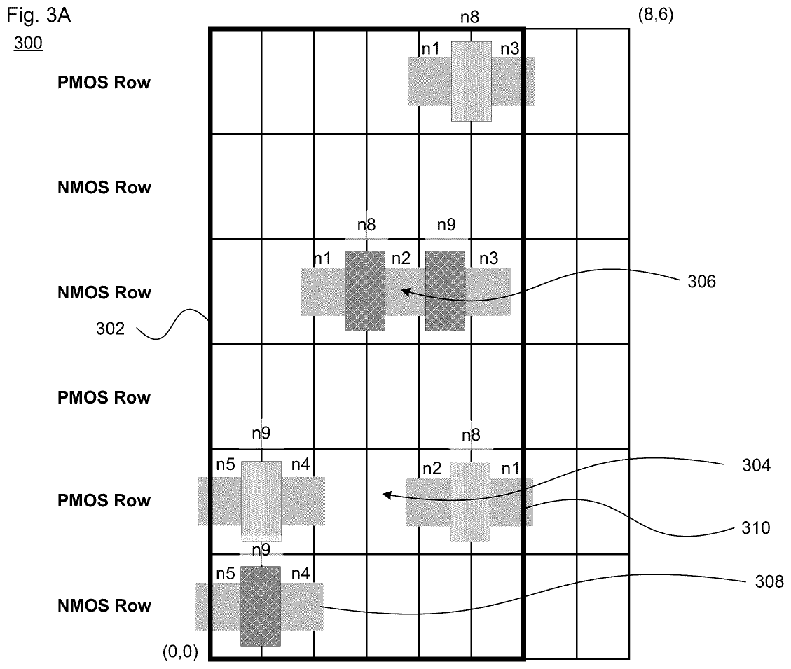

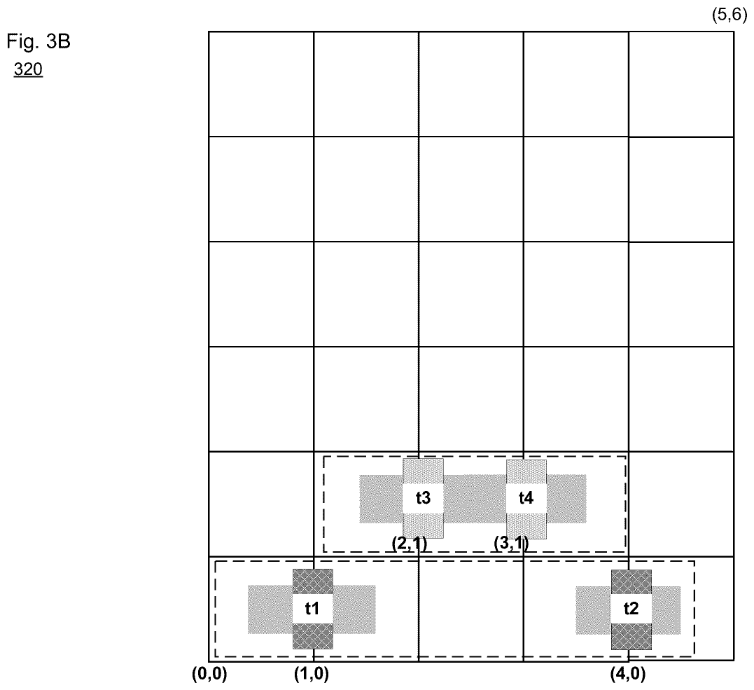

In view of this, a reinforcement learning process is performed to determine an order of transistor placement before the subsequent placement procedure, such as SAT-based placement, is run. This involves the use of an encoded grid. By way of example, FIG. 3A illustrates a grid 300, also referred to here as a transistor placement canvas. In this example, the grid has a coordinate space in a 2-dimensional array between coordinate point (0,0) at the lower left, and coordinate point (8,6) at the top right. In this exemplary scenario, a number of NMOS and PMOS transistors fall within the overall grid, and more specifically within rectangular cell area 302. Here, each horizontal row is dedicated for either NMOS or PMOS type transistors. In this example, the lowest row (row 0) is an NMOS transistor row, while the next lowest row (row 1) is a PMOS transistor row. In row 1, there is a diffusion break between the two PMOS transistors as shown by arrow 304 (between n4 of the transistor on the left and n2 of the transistor on the right). In contrast, in row 4 there is a diffusion sharing region (at n2) for the PMOS transistors as shown by arrow 306.

Each transistor, whether NMOS or PMOS, has a lower left x-y coordinate associated with it, where the i^{th} transistor is located at coordinate (xᵢ, yᵢ). For example, NMOS 308 on the lower left grid is at coordinate (0, 0), and PMOS 310 is at coordinate (4, 1). In one aspect of the technology, each transistor is treated as an individual object (with fixed width, e.g., size 3 for the transistors in this example) associated with a coordinate in the multi-dimensional space according to the grid. In another aspect, a linear array can be employed in a one-dimensional space.

When the nets of terminals of two adjacent transistors are the same, these two adjacent transistors are allowed to be overlapped within one column of the grid. The overlapping is also referred to herein as diffusion sharing, which was noted above. This can be seen with the two NMOS transistors at (2,3) and (4,3) via arrow 306. When the nets of terminals of two adjacent transistors are different, these two adjacent transistors need to satisfy a distance d, e.g., d greater than or equal to 2 for transistors in the same row, in the horizontal (x) direction. For example, with the two PMOS transistors at (0,1) and (4,1), d equals 4 (the distance between the end of n4 for the leftmost transistor and the beginning of n2 for the rightmost transistor).

FIG. 3B illustrates another example 320 of a placement canvas where an encoded grid is employed to determine the relative position of transistors (here, transistors t1, t2, t3 and t4). With grid encoding, x represents the horizontal column location, and y represents the vertical sub-cell row. Using the coordinates of the encoding grid, a solver (e.g., SMT or MILP) takes the relative position constraints (generated by the RL framework), as input. In the example shown in FIG. 3B, this may result in the following.

For the transistors t3 and t4:

$$x 4 >= x 3 + w 3 \\ y 3 = y 4 = 1$$

And for the transistors t1 and t2:

$$x 2 >= x 1 + w 1 \\ y 1 = y 2 = 0$$

Here, w1 and w3 are the width of t1 and t3, respectively. Using coordinates and widths of transistors to express the relative constraints in this manner simplifies and accelerates the SAT (or other) solving process.

The reinforcement learning action space of the RL agent is the number of grid points at the encoded grid in FIG. 3B. The RL agent implemented by a machine learning processing system considers the x/y coordinate of the encoded grid to learn the transistor placement ordering. The action space is large enough to accommodate all transistors to be placed. There may be empty spaces left among transistors after RL-based placement phase is finished. Subsequent optimization, such as SAT with relative placement constraints, can then be performed to minimize the white spaces between transistors.

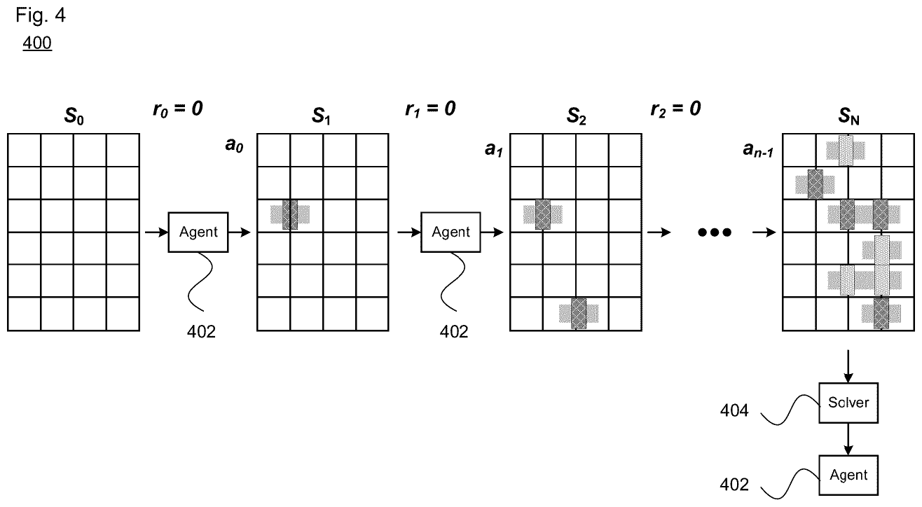

FIG. 4 illustrates an example 400 of an iterative RL training process that can be implemented via the processing system, in which one transistor (or PN transistor pair) is placed at a time on the encoded grid. Due to the CMOS technology styles, in many cases NMOS and PMOS transistors naturally form a pair, which means that physically they share gate/source/drain connections. Thus, a PN grouping heuristic can be used to detect pairs of NMOS/PMOS, so that the agent 402 places pairs of NMOS/PMOS transistors, instead of placing one single transistor at a time. This may significantly speed up the search and generate a more routable transistor-level placement.

As shown, starting with an empty grid in an initial stage, for each training iteration of the RL training process, an RL agent 402 places transistors one at a time (or one PN pair at a time). In FIG. 4, actions, states and rewards are denoted by aᵢ, Sᵢ, and rᵢ, respectively. Actions correspond to placement of a single transistor or a transistor pair on the encoded grid. Each state Sᵢ is a snapshot with transistors placed on the encoded grid (canvas). The states (also known as observations) include the connectivity of placed transistors, x and y coordinates of placed transistors, and a current transistor to place. When the RL agent places another transistor (or PN transistor pair), the system goes from one state to another.

As shown in FIG. 4, the intermediate rewards (e.g., r₀, rᵢ, and r₂) are zero. The final reward (PPAC) may only be evaluated when all transistors are placed and routed at the end of the RL episode. Unlike other RL applications, intermediate rewards here are unnecessary. The final reward is the objective cost to be optimized. Thus, according to one aspect, before training there is a reward assignment process, in which the final reward is propagated back to intermediate steps with a reward discount factor of 0. This way, all intermediate steps are assigned the same reward as the final step.

The reward at the end of each iteration can be calculated as a linear combination of the cell area, wirelength, and routability penalty (pᵣₒᵤₜₑ). Each iteration ends when the selected transistors are placed. More specifically, at the end of each state S_{N}, the reward r_{N} can be expressed as:

$${r}_{N} = - 1 * ( {w}_{a} * Cell Area + \sum {w}_{i , j} * ( \vert {x}_{i} - {x}_{j} \vert + \vert {y}_{i} = {y}_{j} \vert ) + {\sum }_{i}^{K} {w}_{i} * ( \vert {x}_{i , n} - {x}_{i , p} \vert + \vert {y}_{i , n} - {y}_{i , p} \vert ) + ( 1 - routable ) * {p}_{route} )$$

In one scenario, a version of the framework may keep searching for a routable solution while accommodating the cost increase. In other words, this would not guarantee the cost always goes down during the RL search, especially during the early phase of the RL search.

Routability may be checked by a router in one example. The router here may be implemented using SMT, MILP and/or maze routing functions. In the above equation, pᵣₒᵤₜₑ represents a penalty added to the reward function if the placement generated from the RL agent is unroutable.

In another example, the system can approximate routability using congestion, e.g., the ratio between estimated routing track usages based on net terminal locations and the provided routing track resources, and pin density, e.g., the number of input/output terminals of transistors within a fixed-size window. In a further example, the system can approximate routability with a machine learning model using supervised training, which adopts congestion, pin density, e.g., as the input features, or directly adopts the placement of transistors as input features.

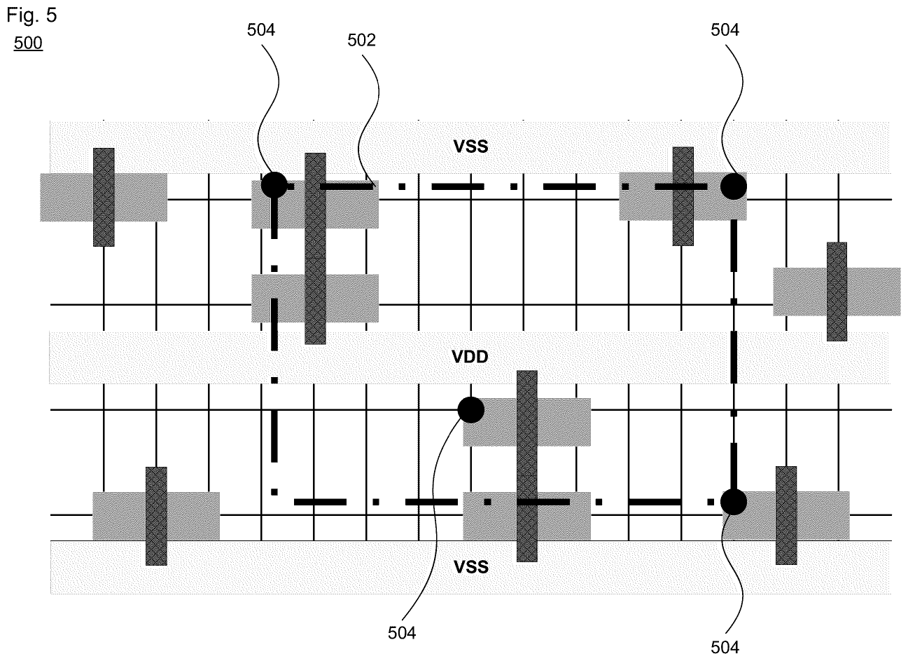

The value of r denotes whether the cell area is routable or not. In the above equation, Cell Area may be defined by a minimum bounding box that includes all the transistors on the transistor placement canvas at that particular stage of the process, wₐ is the weighting of the area; and K is the number of PMOS+NMOS transistors. FIG. 5 illustrates an example 500 showing a minimum bounding box 502 representing the half-perimeter wire length (HPWL). Here, dots 504 indicate pins of the same net. The weighted sum of the HPWL is expressed as:

$$\sum {w}_{i , j} * ( \vert {x}_{i} - {x}_{j} \vert + \vert {y}_{i} = {y}_{j} \vert$$

The reward at the end of each iteration may be a function of area, HPWL, PMOS/NMOS pairing cost, and/or routability. The final reward (after all transistors are placed), can be back-propagated through the machine learning model to one or more of the intermediate states, with or without discount (i.e., penalty). This ensures that the final reward is credited properly to earlier steps in the trajectory.

Returning to FIG. 4, in one implementation once the RL agent 402 determines the coordinates of placed transistors on the encoded grid, then the processing system employs a solver 404, which uses an optimization scheme (e.g., SMT or MILP) to generate the optimum area, HPWL, and/or routability considering transistor flipping, diffusion sharing, and diffusion break constraints. Thus, it can be seen that the RL phase is used to determine the placement order of transistors, and subsequently, a fast optimization technique or greedy heuristics is employed by solver 404, with the order of transistors as input, to determine the exact location, e.g., (x, y) coordinate, of each transistor.

In one scenario, the system may call the solver 404 at one or more intermediate stages of the RL agent operation. This can provide the RL agent a more accurate signal for guided search. Additionally or alternatively to the above approaches, the RL agent 402 may be called once more after the solver 404 is finished. In FIG. 4, from S₁ to S_{N} with all transistors placed, that is one iteration of the RL to determine the transistor order, the RL agent may rely on the solver to return the current reward of the transistor placement. Hence, the RL agent may clear out the canvas and redo transistor placement based on the reward from previous iteration.

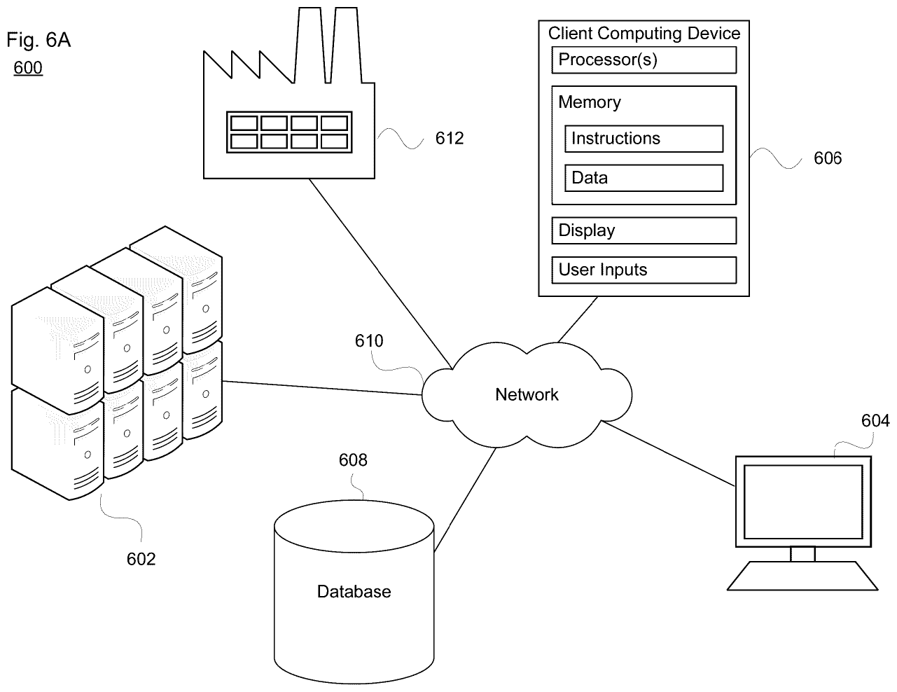

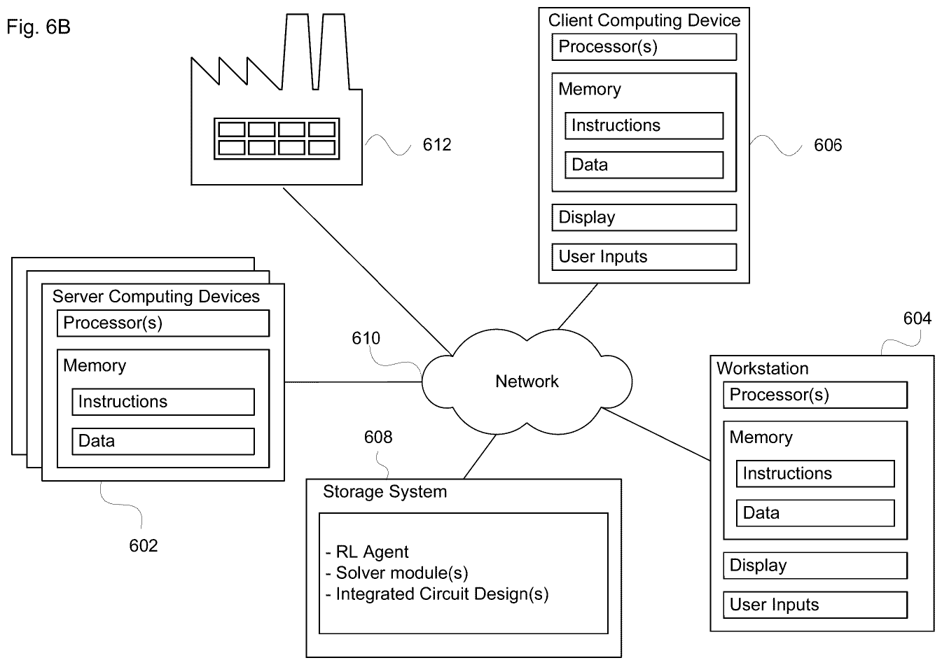

One example of a system configured to perform integrated circuit design and fabrication is shown in FIGS. 6A-B. In particular, FIG. 6A is a block diagram and FIG. 6B is a functional diagram, of an example system 600 that includes a plurality of computing devices 602, 604, 606 and a storage system 608 connected via a network 610. System 600 may also include a fabrication facility 612 that is configured to produce integrated circuits designed according to the processes described herein. As shown in FIG. 6B, each of computing devices 602, 604 and 606 may include one or more processors, memory, data and instructions.

By way of example, the one or more processors may be any conventional processors, such as commercially available central processing units (CPUs), graphical processing units (GPUs) or tensor processing unites (TPUs). Alternatively, the one or more processors may include a dedicated device such as an ASIC or other hardware-based processor. As shown in FIG. 6B, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. The data may be retrieved, stored or modified by processor in accordance with the instructions. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 600 and/or the fabrication facility 612.

The various computing devices may communicate directly or indirectly via one or more networks, such as network 610. The network 610 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 602 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 602 may include one or more server computing devices that are capable of communicating with computing devices 604, 606 and the fabrication facility 612 via the network 610.

The computing devices 602 may be configured to implement the RL agent and perform the iterative approach shown in FIG. 4, according to a machine learning framework, e.g., a TensorFlow framework. See, for instance, “Scalability and Generalization of Circuit Training for Chip Floorplanning”, by Yue et al., 2022, the entire disclosure of which is incorporated herein by reference. As such, the computing devices 602 may comprise one or more clusters of processing devices in a distributed processing system that is configured for parallel training.

In some examples, client computing device 604 may be an engineering workstation used by a developer to perform circuit design and/or other processes for integrated circuit design and fabrication. Client computing device 606 may also be used by a developer, for instance to prepare system requirements for the integrated circuit or manage the manufacturing process with the fabrication facility 612.

Storage system 608 can be of any type of computerized storage capable of storing information accessible by the server computing devices 602, 604 and/or 606, such as a hard-drive, memory card, ROM, RAM, DVD, CD-ROM, flash drive and/or tape drive. In addition, storage system 608 may include a distributed storage system where data is stored on a plurality of different storage devices which may be physically located at the same or different geographic locations. Storage system 208 may be connected to the computing devices via the network 610 as shown in FIGS. 6A-B, and/or may be directly connected to or incorporated into any of the computing devices.

Storage system 608 may store various types of information. For instance, the storage system 608 may store transistor-level netlists and/or other integrated circuit requirements. Alternatively or additionally, it may store the RL agent, one or more solver modules, and any final IC designs to be provided for circuit fabrication by facility 612.

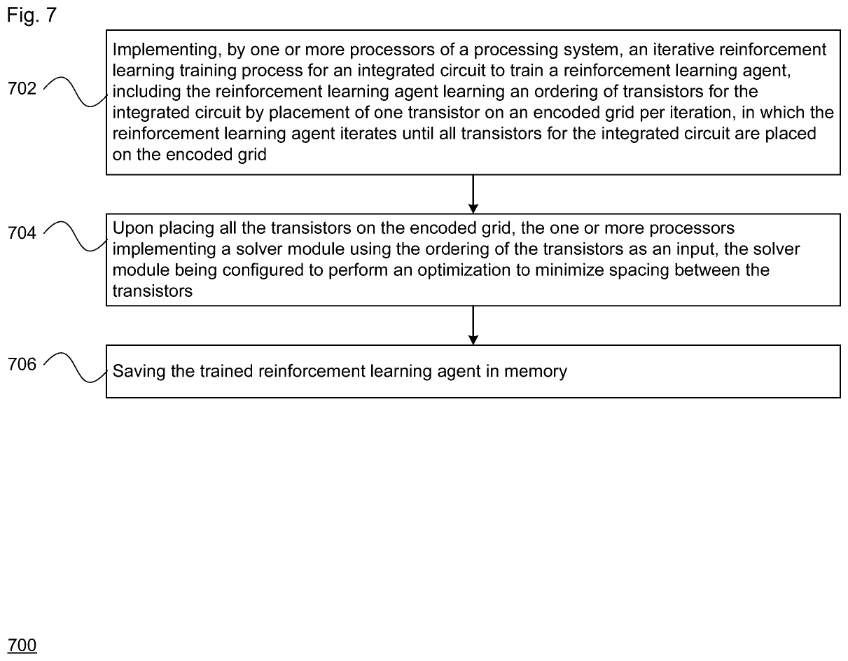

FIG. 7 illustrates a flow diagram 700 for a process in view of the above discussion. The process includes, at block 702, implementing, by one or more processors of a processing system, an iterative reinforcement learning training process for an integrated circuit to train a reinforcement learning agent. This includes the reinforcement learning agent learning an ordering of transistors for the integrated circuit by placement of one transistor on an encoded grid per iteration. The reinforcement learning agent iterates until all transistors for the integrated circuit are placed on the encoded grid; upon placing all the transistors on the encoded grid. At block 704, the one or more processors implement a solver module using the ordering of the transistors as an input, in which the solver module is configured to perform an optimization to minimize spacing between the transistors. Then at block 706 the process includes saving the trained reinforcement learning agent in memory

Although the technology herein has been described with reference to particular embodiments, it is to be understood that these embodiments are merely illustrative of the principles and applications of the present technology. It is therefore to be understood that numerous modifications may be made to the illustrative embodiments and that other arrangements may be devised without departing from the spirit and scope of the present technology as defined by the appended claims.

1. A computer-implemented processing system, comprising:
a memory configured to store a reinforcement learning agent and a solver module; and
one or more processors operatively coupled to the memory, the one or more processors being configured to:
implement an iterative reinforcement learning training process for an integrated circuit to train the reinforcement learning agent, in which the reinforcement learning agent learns an ordering of transistors for the integrated circuit by placement of one transistor on an encoded grid per iteration, in which the reinforcement learning agent is configured to iterate until all transistors for the integrated circuit are placed on the encoded grid;
upon placement of all the transistors on the encoded grid, implement the solver module using the ordering of the transistors as an input, the solver module being configured to perform an optimization to minimize spacing between the transistors; and
save the trained reinforcement learning agent in the memory.

2. The processing system of claim 1, wherein the one or more processors are further configured to generate an integrated circuit design according to the optimization.

3. The processing system of claim 1, wherein the reinforcement learning agent learns the ordering of transistors for the integrated circuit by placing either the one transistor on the encoded grid per iteration or by placing a pair of complementary transistors on the encoded grid per iteration.

4. The processing system of claim 1, wherein the reinforcement learning agent employs a policy proximal optimization according to an RL action space.

5. The processing system of claim 4, wherein the policy proximal optimization implements a probability distribution for every transistor for where that could be placed on the encoded grid.

6. The processing system of claim 1, wherein the one or more processors are further configured to implement a router module after one or more intermediate iterations of the iterative reinforcement learning training process.

7. The processing system of claim 1, wherein the solver module implements at least one of a Boolean Satisfiability solver, a Satisfiability Modulo a Theory (SMT) solver, or a Mixed-Integer Linear Programming (MILP) solver.

8. The processing system of claim 1, wherein the reinforcement learning agent learns the ordering of transistors according to actions, states and rewards for each iteration, in which each state includes connectivity and coordinates of previously placed transistors on the encoded grid.

9. The processing system of claim 8, wherein the reward at an end of each iteration is calculated as a linear combination of cell area, wirelength, and any routability or timing penalty.

10. The processing system of claim 9, wherein cell area is defined by a minimum bounding box that includes all currently placed transistors at a given iteration.

11. The processing system of claim 10, wherein the minimum bounding box represents a half-perimeter wire length.

12. The processing system of claim 8, wherein the reward at a conclusion of a final iteration is back-propagated through the reinforcement learning agent.

13. The processing system of claim 1, wherein routability at each iteration is approximated using at least one of congestion, pin density, area or wire length.

14. A computer-implemented method, comprising:
implementing, by one or more processors of a processing system, an iterative reinforcement learning training process for an integrated circuit to train a reinforcement learning agent, including the reinforcement learning agent learning an ordering of transistors for the integrated circuit by placement of one transistor on an encoded grid per iteration, in which the reinforcement learning agent iterates until all transistors for the integrated circuit are placed on the encoded grid;
upon placing all the transistors on the encoded grid, the one or more processors implementing a solver module using the ordering of the transistors as an input, the solver module being configured to perform an optimization to minimize spacing between the transistors; and
saving the trained reinforcement learning agent in memory.

15. The method of claim 14, further comprising generating an integrated circuit design according to the optimization.

16. The method of claim 14, wherein learning the ordering of transistors for the integrated circuit by the reinforcement learning agent includes placing either the one transistor on the encoded grid per iteration or by placing a pair of complementary transistors on the encoded grid per iteration.

17. The method of claim 14, wherein the reinforcement learning agent employs a policy proximal optimization according to an RL action space.

18. The method of claim 14, further comprising the one or more processors implementing a router module after one or more intermediate iterations of the iterative reinforcement learning training process.

19. The method of claim 14, wherein the solver module implements at least one of a Boolean Satisfiability solver, a Satisfiability Modulo a Theory (SMT) solver, or a Mixed-Integer Linear Programming (MILP) solver.

20. The method of claim 14, wherein the reinforcement learning agent learns the ordering of transistors according to actions, states and rewards for each iteration, in which each state includes connectivity and coordinates of previously placed transistors on the encoded grid.
